(19) United States
(12) Patent Application Publication
(10) Pub. No.: US 2007/0295983 A1
(43) Pub. Date: Dec. 27, 2007

(54) Optoelectronic device

(75) Inventor: Deborah Ann Haitko, Schenectady, NY (US)

Correspondence Address: FAY SHARPE LLP, 1100 SUPERIOR AVENUE, SEVENTH FLOOR, CLEVELAND, OH, 44114, US

(73) Assignee: GELcore LLC

(21) Appl. No.: 11/475,800

(22) Filed: Jun. 27, 2006

(51) Int. Cl. H01L 33/00

(52) U.S. Cl. 257/100

(57) ABSTRACT

The present invention provides an optoelectronic device comprising a light emitting semiconductor and an encapsulant. The encapsulant is made from an encapsulant formulation comprising an epoxy isocyanurate such as formula (I-1) compound, and a curing agent. The present invention also provides a method of preparing such optoelectronic device.

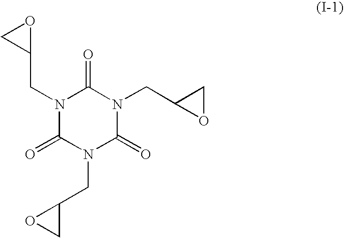

### BACKGROUND OF THE INVENTION

The present invention is related to an optoelectronic device and method thereof. More particularly, the present invention provides an optoelectronic device comprising a light emitting semiconductor and an encapsulant. The encapsulant is made from an encapsulant formulation comprising an epoxy isocyanurate and a curing agent.

In developing a satisfactory encapsulant for an optoelectronic device, one needs to consider a wide range of factors and the balance between them, such as thermal stability, low coefficient of thermal expansion (CTE), UV stability, oxidative stability, moisture resistance, optical clarity, transparency, lumen output, power consumption, quantum efficiency, wavelength conversion, structural integrity, hardness, thermal compliance, crack resistance, reliability, viscosity, curing properties, manufacturability, and cost effectiveness, among others. For example, light emitting active layers need excellent thermal and UV properties to withstand intense light at wavelengths between 470 nm and 380 nm. The encapsulants employed in LED packages also need to be tolerant to shorter wavelengths, e.g. around 400 nm.

Conventional encapsulations of optoelectronic devices have primarily relied on blends of bisphenol-A epoxy resins and aliphatic anhydride curing agents. As described in U.S. Pat. No. 4,178,274, one disadvantage of these compositions is that, because of the aromatic character of bisphenol-A based epoxy resins, they are typically less stable when exposed to ultraviolet radiation and may degrade on extended exposure to ultraviolet light. Other cycloolefin copolymer based encapsulants, for example, can fail due to thermal degradation.

Prototypes of UV light emitting LED have been prepared by Nichia Chemical Industries using inert gas filled glass encased devices; however, the devices are prohibitively expensive.

Advantageously, the present invention provides an improved optoelectronic device, the encapsulant of which has increased UV and thermal stabilities, improved curing properties such as B or C stage curing capability, and higher glass transition temperature (T_{g}), among others.

### BRIEF DESCRIPTION OF THE INVENTION

One aspect of the present exemplary embodiment is to provide an optoelectronic device comprising a light emitting semiconductor and an encapsulant. The encapsulant is made from an encapsulant formulation comprising an epoxy isocyanurate such as formula (I-1) compound, and a curing agent. The encapsulant may optionally be made from an encapsulant formulation comprising an epoxy isocyanurate such as formula (I-1) compound, an aliphatic or cycloaliphatic epoxy, a hardener or curing agent.

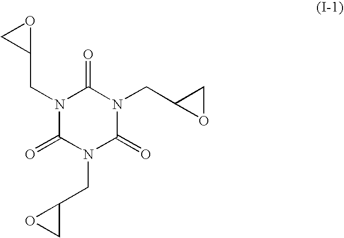

Another aspect of the present exemplary embodiment is to provide a method of preparing an optoelectronic device, which comprises (i) providing a light emitting semiconductor, and (ii) encapsulating the light emitting semiconductor with an encapsulant that is made from a formulation comprising an epoxy isocyanurate and a curing agent. The encapsulant may optionally be made from an encapsulant formulation comprising an epoxy isocyanurate such as formula (I-1) compound, an aliphatic or cycloaliphatic epoxy, a hardener or curing agent.

### BRIEF DESCRIPTION OF THE DRAWINGS

FIG. 1 shows a schematic diagram of a LED device according to an embodiment of the present invention;

FIG. 2 shows a schematic diagram of a LED array on a substrate according to one embodiment of the present invention;

FIG. 3 shows a schematic diagram of a LED device according to another embodiment of the present invention; and

FIG. 4 shows a schematic diagram of a vertical cavity surface emitting laser device according to still another embodiment of the present invention.

### DETAILED DESCRIPTION OF THE INVENTION

The present invention provides an optoelectronic device that comprises a light emitting semiconductor and an encapsulant. The light emitting semiconductor may be a light emitting diode (LED) or a laser diode. The encapsulant is made from an encapsulant formulation comprising an epoxy isocyanurate and a curing agent. The encapsulant may optionally be made from an encapsulant formulation comprising an epoxy isocyanurate, an aliphatic or cycloaliphatic epoxy, a hardener or curing agent. Also included within the scope of the present invention are methods of preparing such optoelectronic device.

Optoelectronic device of the invention may be any solid-state and other electronic device for generating, modulating, transmitting, and sensing electromagnetic radiation in the ultraviolet, visible, and infrared portions of the spectrum. Optoelectronic devices, sometimes referred to as semiconductor devices or solid state devices, include, but are not limited to, light emitting diodes (LEDs), charge coupled devices (CCDs), photodiodes, vertical cavity surface emitting lasers (VCSELs), phototransistors, photocouplers, opto-electronic couplers, and the like. However, it should be understood that the encapsulant formulation can also be used in devices other than an optoelectronic device, for example, logic and memory devices, such as microprocessors, ASICs, DRAMs and SRAMs, as well as electronic components, such as capacitors, inductors and resistors, among others.

Several non-limiting examples of optoelectronic devices of the present invention are illustrated in the accompanying drawings. These figures are merely schematic representations based on convenience and the ease of demonstrating, and are, therefore, not intended to indicate relative size and dimensions of the optoelectronic devices or components thereof.

Although specific terms are used in the following description for the sake of clarity, these terms are intended to refer only to the particular structure of the embodiments selected for illustration in the drawings, and are not intended to define or limit the scope of the invention. In the drawings and the following description below, it is to be understood that like numeric designations refer to component of like function.

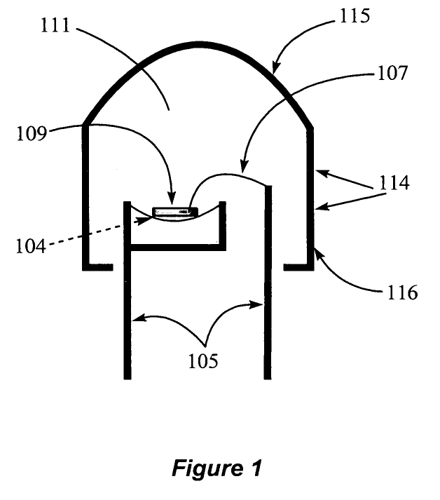

With reference to FIG. 1, a device according to one embodiment of the present invention is schematically illustrated. The device contains a LED chip 104, which is electrically connected to a lead frame 105. For example, the LED chip 104 may be directly electrically connected to an anode or cathode electrode of the lead frame 105 and connected by a lead 107 to the opposite cathode or anode electrode of the lead frame 105, as illustrated in FIG. 5. In a particular embodiment illustrated in FIG. 5, the lead frame 105 supports the LED chip 104. However, the lead 107 may be omitted, and the LED chip 104 may straddle both electrodes of the lead frame 105 with the bottom of the LED chip 104 containing contact layers, which contact both the anode and cathode electrode of the lead frame 105. The lead frame 105 connects to a power supply, such as a current or voltage source or to another circuit (not shown).

The LED chip 104 emits radiation from the radiation emitting surface 109. The LED may emit visible, ultraviolet or infrared radiation. The LED chip 104 may be any LED chip containing a p-n junction of any semiconductor layers capable of emitting the desired radiation. For example, the LED chip 104 may contain any desired Group III-V compound semiconductor layers, such as GaAs, GaAlAs, GaN, InGaN, GaP, etc., or Group II-VI compound semiconductor layers such as ZnSe, ZnSSe, CdTe, etc., or Group IV-IV semiconductor layers, such as SiC. The LED chip 104 may also contain other layers, such as cladding layers, waveguide layers and contact layers.

The LED is packaged with an encapsulant 111 prepared according to the present invention. In one embodiment, the encapsulant 111 is used with a shell 114. The shell 114 may be any plastic or other material, such as polycarbonate, which is transparent to the LED radiation. However, the shell 114 may be omitted to simplify processing if encapsulant 111 has sufficient toughness and rigidity to be used without a shell. Thus, the outer surface of encapsulant 111 would act in some embodiments as a shell 114 or package. The shell 114 contains a light or radiation emitting surface 115 above the LED chip 104 and a non-emitting surface 116 adjacent to the lead frame 105. The radiation emitting surface 115 may be curved to act as a lens and/or may be colored to act as a filter. In various embodiments the non-emitting surface 116 may be opaque to the LED radiation, and may be made of opaque materials such as metal. The shell 114 may also contain a reflector around the LED chip 104, or other components, such as resistors, etc., if desired.

According to the present invention, a phosphor may be coated as a thin film on the LED chip 104; or coated on the inner surface of the shell 114; or interspersed or mixed as a phosphor powder with encapsulant 111. Any suitable phosphor material may be used with the LED chip. For example, a yellow emitting cerium doped yttrium aluminum garnet phosphor (YAG:Ce³⁺) may be used with a blue emitting InGaN active layer LED chip to produce a visible yellow and blue light output which appears white to a human observer. Other combinations of LED chips and phosphors may be used as desired. A detailed disclosure of a UV/blue LED-Phosphor Device with efficient conversion of UV/blue Light to visible light may be found in U.S. Pat. No. 5,813,752 (Singer) and U.S. Pat. No. 5,813,753 (Vriens).

While the packaged LED chip 104 is supported by the lead frame 105 according to one embodiment as illustrated in FIG. 1, the device can have various other structures. For example, the LED chip 104 may be supported by the bottom surface 116 of the shell 114 or by a pedestal (not shown) located on the bottom of the shell 114 instead of by the lead frame 105.

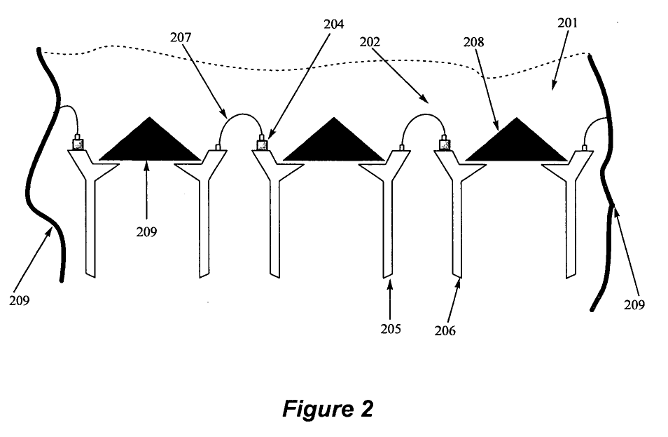

With reference to FIG. 2, a device including a LED array fabricated on a plastic substrate is illustrated. LED chips or dies 204 are physically and electrically mounted on cathode leads 206. The top surfaces of the LED chips 204 are electrically connected to anode leads 205 with lead wires 207. The lead wires may be attached by known wire bonding techniques to a conductive chip pad. The leads 206, 205 comprise a lead frame and may be made of a metal, such as silver plated copper. The lead frame and LED chip array are contained in a plastic package 209, such as, for example, a polycarbonate package, a polyvinyl chloride package or a polyetherimide package. In some embodiments, the polycarbonate comprises a bisphenol A polycarbonate. The plastic package 209 is filled with an encapsulant 201 made from an encapsulant formulation according to the present invention. The package 209 contains tapered interior sidewalls 208, which enclose the LED chips 204, and form a light spreading cavity 202, which ensures cross fluxing of LED light.

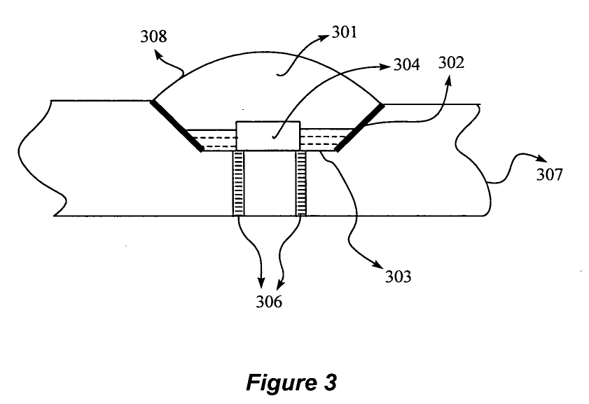

FIG. 3 shows a device in which the LED chip 304 is supported by a carrier substrate 307. With reference to FIG. 3, the carrier substrate 307 comprises a lower portion of the LED package, and may comprise any material, such as plastic, metal or ceramic. Preferably, the carrier substrate is made out of plastic and contains a groove 303 in which the LED chip 304 is located. The sides of the groove 303 may be coated with a reflective metal 302, such as aluminum, which acts as a reflector. However, the LED chip 304 may be formed over a flat surface of the substrate 307 as well. The substrate 307 contains electrodes 306 that electrically contact the contact layers of the LED chip 304. Alternatively, the electrodes 306 may be electrically connected to the LED chip 304 with one or two leads as illustrated in FIG. 3. The LED chip 304 is covered with an encapsulant 301 that is made from the encapsulant formulation of the present invention. If desired, a shell 308 or a glass plate may be formed over the encapsulant 301 to act as a lens or protective material.

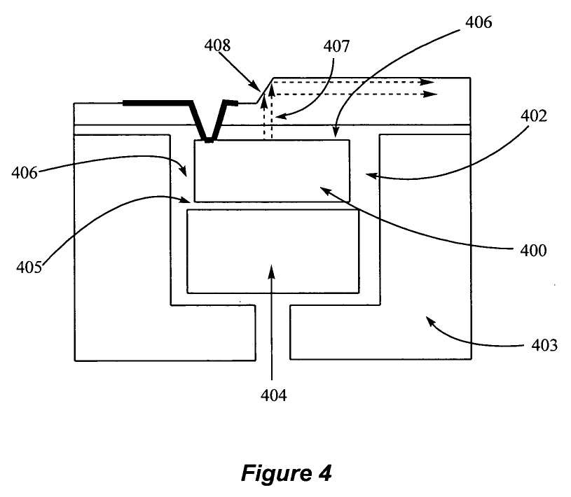

A vertical cavity surface emitting laser (VCSEL) is illustrated in FIG. 4. With reference to FIG. 4, a VCSEL 400 may be embedded inside a pocket 402 of a printed circuit board assembly 403. A heat sink 404 may be placed in the pocket 402 and the VCSEL 400 may rest on the heat sink 404. The encapsulant 406 may be formed by filling, such as injecting, an encapsulant formulation of the invention into the cavity 405 of the pocket 402 in the printed circuit board 403, which may flow around the VCSEL and encapsulate it on all sides and also form a coating top film 406 on the surface of the VCSEL 400. The top coating film 406 may protect the VCSEL 400 from damage and degradation and at the same time may also be inert to moisture, transparent and polishable. The laser beams 407 emitting from the VCSEL may strike the mirrors 408 to be reflected out of the pocket 402 of the printed circuit board 403.

As described supra, the present invention provides an optoelectronic device that comprises a light emitting diode and an encapsulant. The encapsulant is made from an encapsulant formulation comprising an epoxy isocyanurate and a curing agent.

In some exemplary embodiments, the encapsulant is made from an encapsulant formulation comprising an epoxy isocyanurate, an aliphatic or cycloaliphatic epoxy, hardener, and curing agents.

It is to be understood herein, that if a “range” or “group” is mentioned with respect to a particular characteristic of the present disclosure, for example, percentage, chemical species, and temperature etc., it relates to and explicitly incorporates herein each and every specific member and combination of sub-ranges or sub-groups therein whatsoever. Thus, any specified range or group is to be understood as a shorthand way of referring to each and every member of a range or group individually as well as each and every possible sub-range or sub-group encompassed therein; and similarly with respect to any sub-ranges or sub-groups therein.

The epoxy isocyanurate of the invention is defined herein as a compound that contains two structural units, the first of which is an isocyanurate group of formula (Iₐ) with one or more hydrogen atoms removed, and the second of which is an epoxy group of formula (I_{b}):

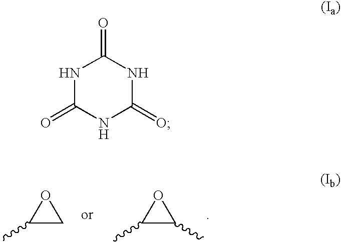

In a variety of exemplary embodiments, the formula (I_{b}) epoxy group may be represented as one of the followings:

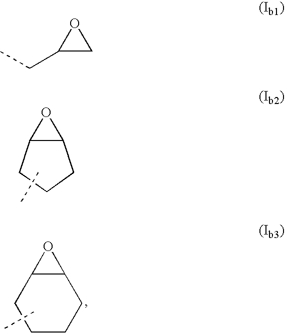

in which the dashed line represents any linker group such as a C₁₋₆ alkylene group that connects the epoxy group and an isocyanurate nitrogen atom.

For example, the epoxy isocyanurate may be selected from one or more compounds having the following formulas:

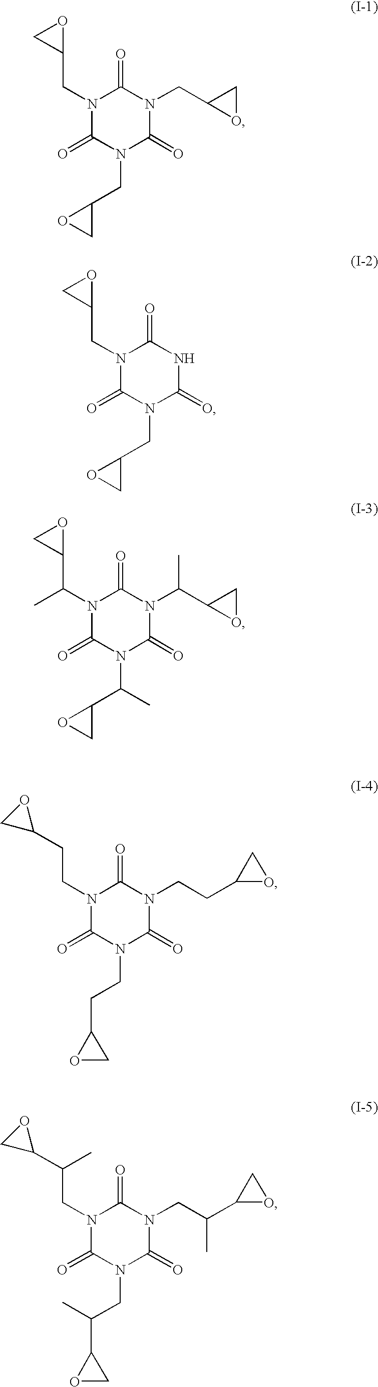

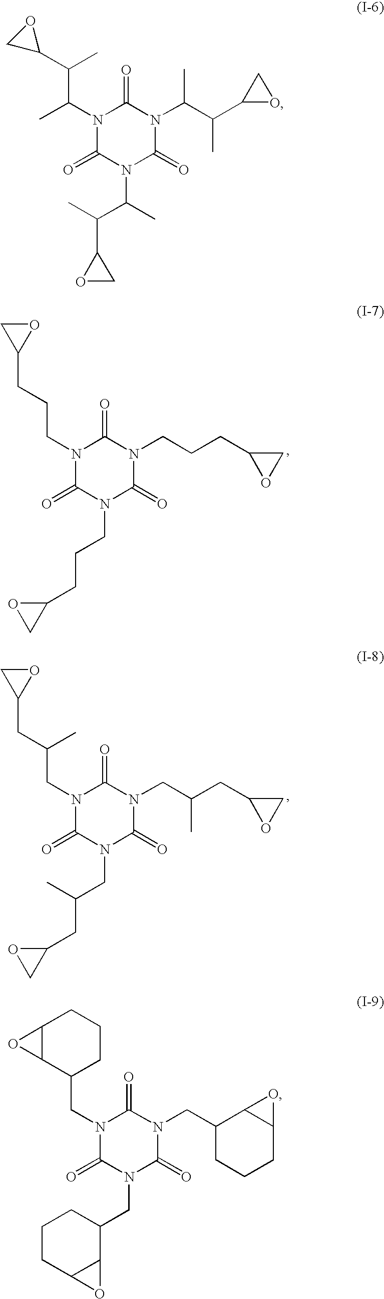

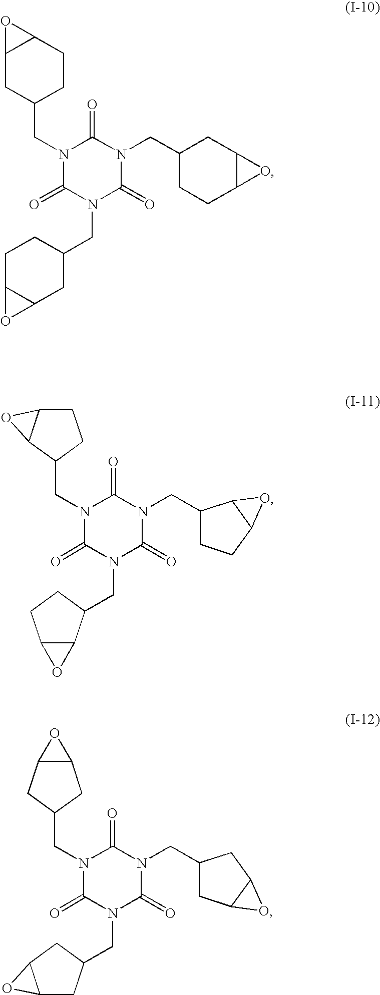

and the like, and the mixture thereof.

In a specific embodiment, the epoxy isocyanurate comprises a compound of formula (I-1) (TGIC) as shown below:

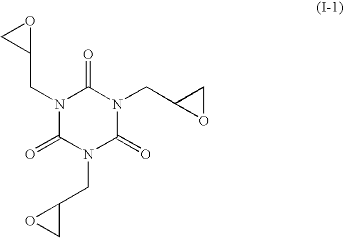

The amount of the epoxy isocyanurate is greater than about 5% by weight, preferably between about 10% and about 50%, more preferably between about 20% and about 40%, based on the total weight of the encapsulant formulation.

The epoxy isocyanurate may be used, alone or optionally in combination with one or more suitable epoxy compounds other than the epoxy isocyanurate (hereinafter “other epoxy compound”) in the encapsulant formulation. Examples of such epoxy compounds include, but are not limited to, aliphatic multiple-epoxy compounds, cycloaliphatic multiple-epoxy compounds, and mixtures thereof. For example, cycloaliphatic multiple-epoxy compounds may be selected from the ERL series epoxies from Ciba-Geigy such as the formula (E-1) compound, which is commonly known as ERL 4221; the formula (E-2) compound, which is commonly known as ERL 4206; the formula (E-3) compound, which is commonly known as ERL 4234; the formula (E-4) compound, which is commonly known as ERL 4299; and the like; and the mixture thereof.

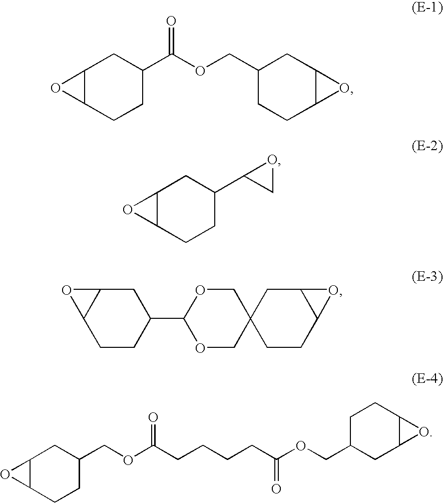

Exemplary aliphatic multiple-epoxy compounds include, but are not limited to, butadiene dioxide, dimethylpentane dioxide, diglycidyl ether, 1,4-butanedioldiglycidyl ether, diethylene glycol diglycidyl ether, dipentene dioxide, polyoldiglycidyl ether, and the like, and mixture thereof.

Other specific exemplary aliphatic multiple-epoxy compounds include, but are not limited to the following structures:

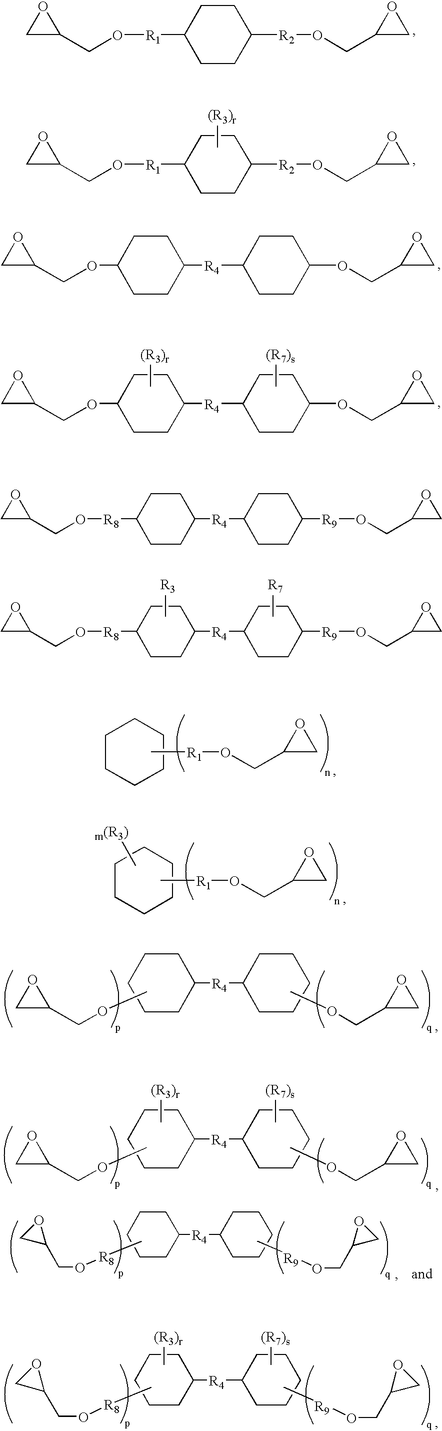

wherein R₁ and R₂ are independently of each other a C₁₋₁₀ divalent hydrocarbon group; R₃ and R₇ are independently of each other selected from the group consisting of OH, alkyl, alkenyl, hydroxyalkyl, hydroxyalkenyl, and C₁₋₁₀ alkoxy; R₄, R₈, and R₉ are independently of each other selected from the group consisting of hydroxyalkylene, hydroxyalkenylene, R₁, R₂, —R,—S—R₂—, —R₁—N(R₅)(R₂)—, and —C(R₅)(R₆)—, wherein R₅ and R₆ are independently selected from the group consisting of H, OH, alkyl, alkoxy, hydroxyalkyl, alkenyl, and C₁₋₁₀ hydroxyalkenyl; n is an integer from 2 to 6, inclusive; m is an integer from 0 to 4, inclusive; 2≦m+n≦6; p and q are independently of each other selected from the group of integers from 1 to 5, inclusive; r and s are independently selected from the group of integers from 0 to 4, inclusive; 2≦p+r≦5; and 2≦q+s≦5.

Exemplary cycloaliphatic multiple-epoxy compounds include, but are not limited to, 2-(3,4-epoxy)cyclohexyl-5,5-spiro-(3,4-epoxy)cyclohexane-m-dioxane, 3,4-epoxycyclohexyl 3′,4′-epoxycyclohexanecarboxylate (EECH), 3,4-epoxycyclohexylalkyl 3′,4′-epoxycyclohexanecarboxylate, 3,4-epoxy-6-methylcyclohexylmethyl, 3′,4-epoxy-6′-methylcyclohexanecarboxylate, vinyl cyclohexanedioxide, bis(3,4-epoxycyclohexylmethyl)adipate, bis(3,4-epoxy-6-methyl cyclohexylmethyl)adipate, exo-exo bis(2,3-epoxycyclopentyl) ether, endo-exo bis(2,3-epoxycyclopentyl) ether, 2,2-bis(4-(2,3-epoxypropoxy)cyclohexyl)propane, 2,6-bis(2,3-epoxy, propoxycyclohexyl-p-dioxanc), 2,6-bis(2,3-epoxypropoxy) norbonene, the diglycidylether of linoleic acid dimer, limonene dioxide, 2,2-bis(3,4-epoxycyclohexyl)propane, dicyclopentadiene dioxide, 1,2-epoxy-6-(2,3-epoxypropoxy)hexahydro-4,7-methanoindane, p-(2,3-epoxy)cyclopentylphenyl-2,3-epoxypropylether, 1-(2,3-epoxypropoxy)phenyl-5,6-epoxyhexahydro-4,7-methanoindane, o-(2,3-epoxy)cyclopentylphenyl-2,3-epoxypropyl ether), 1,2-bis[5-(1,2-epoxy)-4,7-hexahydromethanoindanoxyl]ethane, cyclopentenylphenyl glycidyl ether, cyclohexanediol diglycidyl ether, diglycidyl hexahydrophthalate, and mixture thereof.

In some embodiments, aromatic epoxy resin can be used. Exemplary aromatic epoxy resin include, but are not limited to, bisphenol-A epoxy resins, bisphenol-F epoxy resins, phenol novolac epoxy resins, cresol-novolac epoxy resins, biphenol epoxy resins, biphenyl epoxy resins, 4,4′-biphenyl epoxy resins, divinylbenzene dioxide resins, 2-glycidylphenylglycidyl ether resins, and the like, and mixture thereof.

The amount of the other epoxy compound(s), if present, in the encapsulant formulation is generally greater than about 40%, preferably between about 50% and about 80%, more preferably between about 60% and about 70% by weight, based on the total weight of the encapsulant formulation.

However, the total amount of epoxy isocyanurate and other optional epoxy compound(s) is generally greater than about 40%, preferably between about 50% and about 90%, more preferably between about 60% and about 80% by weight, based on the total weight of the encapsulant formulation.

In a specific embodiment of the invention, the encapsulant formulation comprises an epoxy isocyanurate of formula (I-1) and an epoxy compound of formula (E-1) (EHEHA).

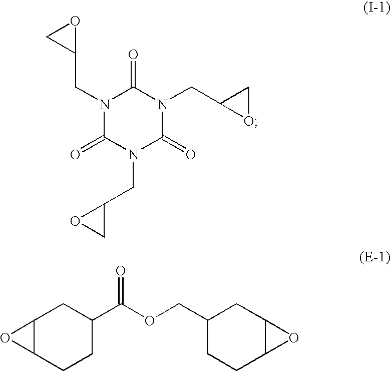

### In the formulation, the amount of formula (I-1) epoxy isocyanurate is between about 10% and about 40%, and the amount of formula (E-1) epoxy compound is between about 10% and about 30%, based on the total weight of the encapsulant formulation.

As described supra, the present invention provides an optoelectronic device that comprises a light emitting diode and an encapsulant. The encapsulant is made from an encapsulant formulation comprising an epoxy isocyanurate and a curing agent. The curing agent may be selected from cycloaliphatic anhydrides, aliphatic anhydrides, polyacids and their anhydrides, polyamides, formaldehyde resins, aliphatic polyamines, cycloaliphatic polyamines, aromatic polyamines, polyamide amines, polycarboxylic polyesters, polysulfides and polymercaptans, phenol novolac resins, and polyols such as polyphenols, among others.

Exemplary anhydride curing agents may be those described in “Chemistry and Technology of the Epoxy Resins” 13. Ellis (Ed.) Chapman Hall, New York, 1993 and in “Epoxy Resins Chemistry and Technology”, edited by C. A. May, Marcel Dekker, New York, 2^{nd} edition, 1988. Non-limiting examples of anhydride are succinic anhydride; dodecenylsuccinic anhydride; phthalic anhydride; tetraahydrophthalic anhydride; hexahydrophthalic anhydride; methylhexahydrophthalic anhydride (“MHHPA”); hexahydro-4-methylphthalic anhydride; tetrachlorophthalic anhydride; dichloromaleic anhydride; pyromellitic dianhydride; chlorendic anhydride; anhydride of 1,2,3,4-cyclopentanetetracarboxylic acid; bicyclo[2.2.1]hept-5-ene-2,3-dicarboxylic anhydride; endo-cis-bicyclo(2.2.1)heptene-2,3-dicarboxylic anhydride; methylbicyclo(2.2.1)heptene-2,3-dicarboxylic anhydride; 1,4,5,6,7,7-hexachlorobicyclo(2.2.1)-5-hept-ene-2,3-dicarboxylic anhydride; anhydrides having the following formula; and the like; and the mixture thereof.

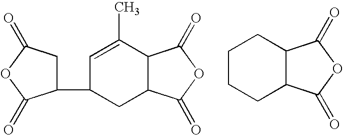

Exemplary polyamine curing agents may be aliphatic polyamines and cycloaliphatic polyamines, such as those disclosed in Clayton A. May and Yoshio Tanaka (Ed.), “Epoxy Resins, Chemistry And Technology,” Marcel Dekker (1973), chapters 3 and 4. Non-limiting examples of polyamine are ethylenediamine; diethylenetriamine; triethylenetetramine; hexamethylenediamine; diethylaminopropylamine; menthanediamine (4-(2-aminopropane-2-yl)1-methylcyclohexane-1-amine); silicon-containing polyamines; N-aminoethyl piperazine; olefin oxide-polyamine adducts such as H₂N(CH₂CH₂NH)₂(CH₂)₂OH, H₂NR^{a}NH(CH₂)₂OH, H₂N(CH₂)₂NHR^{a}NH(CH₂)₂OH, wherein R^{a} is a C₁₋₁₀ hydrocarbon group; glycidyl ether-polyamine adducts; ketimines; and the like.

Suitable cycloaliphatic polyamines are, for example, derivatives of piperazine, such as N-aminoethylpiperazine; derivatives of cycloaliphatic hydrocarbons, such as 1,2-diaminocyclohexane, and isophorone diamine having the following formula.

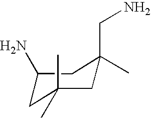

Exemplary polyamide curing agents may be alkyl/alkenyl imidazolines represented by the formula R^{d}—(C(═O)NH—R^{b})ᵤ—NH—R^{c}—NH₂, in which R^{b} and R^{c} are independently of each other a C₁₋₁₀ hydrocarbon group, and R^{d} is selected from the group consisting of H, C₁₋₁₀ alkyl, C₁₋₁₀ alkenyl, C₁₋₁₀ hydroxyalkyl, and C₁₋₁₀ hydroxyalkenyl, and u is an integer from 1-10 inclusive.

Other suitable curing agents include polymercaptan and polyphenol curing agents such as those identified in Chapter 4 of “Epoxy Resins: Chemistry and Technology”, 2^{nd} Edition, edited by C. A. Mory and published by Marcel Dekker Inc.

In a variety of exemplary embodiments, the formulation of the present invention may comprise phenyl imidazoles, aliphatic sulfonium salts, or any mixture thereof.

In a specific embodiment, the curing agent comprises an anhydride with the formula (A-1), alternatively known as hexahydro-4-methylphthalic anhydride, 4-methyl-1,2-cyclohexanedicarboxylic anhydride, or methylhexahydrophthalic anhydride (MHHPA).

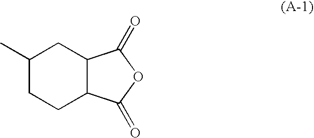

The amount of the curing agent(s) in the encapsulant formulation is generally greater than about 10%, preferably between about 20% and about 60%, more preferably between about 30% and about 60% by weight, based on the total weight of the encapsulant formulation.

In a specific embodiment of the invention, the encapsulant formulation comprises an epoxy isocyanurate of formula (I-1), an epoxy compound of formula (E-1), and an anhydride curing agent of formula (A-1).

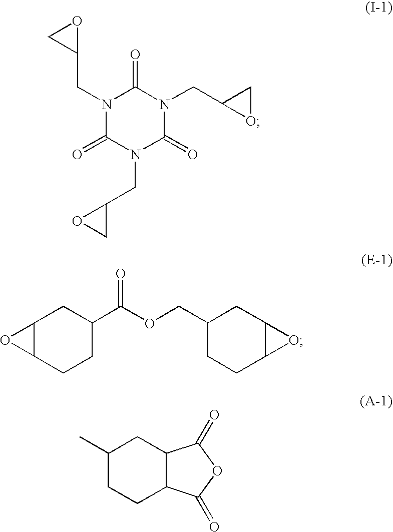

In some embodiments of the invention, particularly when an acid anhydride or a novolac resin is used as the curing agent, the encapsulant formulation may further contain a catalyst or curing accelerator with an object to accelerate the reaction of the epoxy resin and the curing agent.

Suitable catalysts include, for example, imidazole compounds, tertiary amine compounds, phosphine compounds, cycloamidine compounds and the like. Examples of the imidazole compound include, for example, a 2-methylimidazole, a 2-ethyl-4-methylimidazole, and a 2-phenylimidazole.

The amount of the catalyst(s) in the encapsulant formulation is generally greater than about 0.01%, preferably between about 0.01% and about 20%, more preferably between about 0.05% and about 5% by weight, based on the total weight of the encapsulant formulation.

In a specific embodiment of the invention, the encapsulant formulation comprises an epoxy isocyanurate of formula (I-1), an epoxy compound of formula (E-1), an anhydride curing agent of formula (A-1), and a catalyst of formula (C-1), i.e. 2-phenylimidazole.

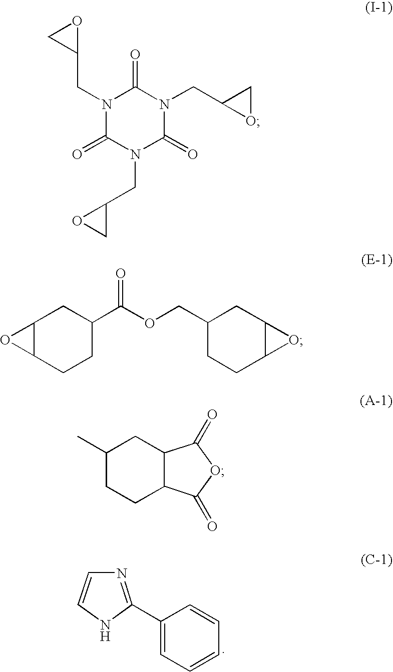

Other suitable catalysts that may be included in the encapsulant formulation are, for example, Boron-containing catalysts. Preferably, a Boron-containing catalyst essentially contains no or a minimal amount of halogen. A minimal amount of halogen means that halogen, if any, is present in such minute quantities that the encapsulant end product is not substantially discolored by the presence of minute quantities of halogen. In a variety of exemplary embodiments, a Boron-containing catalyst may comprise a formula (B-1) or (B-2) compound:

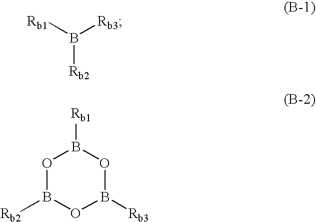

wherein R_{b1}, R_{b2}, and R_{b3} are C₁₋₂₀ aryl, alkyl or cycloalkyl residues and substituted derivatives thereof, or aryloxy, alkyloxy or cycloalkoxy residues and substituted derivatives thereof. Examples of the aforementioned catalysts include, but are not limited to, triphenylborate, tributylborate, trihexylborate, tricyclohexylborate, triphenylboroxine, trimethylboroxine, tributylboroxine, trimethoxyboroxine, and tributoxyboroxine, among others.

Optional components of the encapsulant formulation of the invention may comprise one or more of ancillary curing catalysts. Illustrative examples of ancillary curing catalysts are described in “Chemistry and Technology of the Epoxy Resins” edited by B. Ellis, Chapman Hall, New York, 1993, and in “Epoxy Resins Chemistry and Technology”, edited by C. A. May, Marcel Dekker, New York, 2nd edition, 1988. In particular embodiments, the ancillary curing catalyst comprises at least one of a metal carboxylate, a metal acetylacetonate, a metal octoate or 2-ethylhexanoate as shown below. These compounds can be used singly or in a combination of at least two compounds.

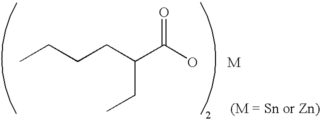

Optional components of the encapsulant formulation of the invention can comprise one or more of cure modifiers which may modify the rate of cure of epoxy. In various embodiments of the present invention, cure modifiers comprise at least one cure accelerator or cure inhibitor. Cure modifiers may comprise compounds containing heteroatoms that possess lone electron pairs. In various embodiments cure modifiers comprise alcohols such as polyfunctional alcohols such as diols, triols, etc., and bisphenols, trisphenols, etc. Further, the alcohol group in such compounds may be primary, secondary or tertiary, or mixtures thereof. Representative examples comprise benzyl alcohol, cyclohexanemethanol, alkyl diols, cyclohexanedimethanol, ethylene glycol, propylene glycol, butanediol, pentanediol, hexanediol such as 2,5-hexylene glycol, heptanediol, octanediol, polyethylene glycol, glycerol, polyether polyols such as those sold under the trade name VORANOL by the Dow Chemical Company, and the like. In a specific embodiment, the cure modifier may be selected from one of the compounds as shown below, or mixture thereof.

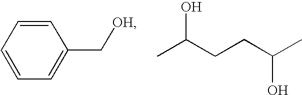

Phosphites may also be used as cure modifiers. Illustrative examples of phosphites comprise trialkylphosphites, triarylphosphites, trialkylthiophosphites, and triarylthiophosphites. In some embodiments phosphites comprise triphenyl phosphite, benzyldiethyl phosphite, or tributyl phosphite. Other suitable cure modifiers comprise sterically hindered amines and 2,2,6,6-tetramethylpiperidyl residues, such as for example bis(2,2,6,6-tetramethylpiperidyl)sebacate. In a specific embodiment, triphenyl phosphite as shown below is used in the encapsulant formulation of the present invention.

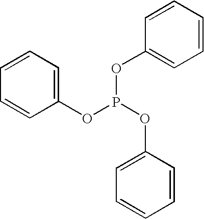

Optional components of the encapsulant formulation of the invention may also comprise coupling agents which in various embodiments may help the encapsulant epoxy resin bind to a matrix, such as a glass matrix, so as to form a strong bond such that premature failure does not occur. In a variety of exemplary embodiments, the coupling agent may have a formula as shown below:

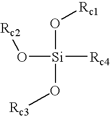

in which R_{c1}, R_{c2}, and R_{c3} are an alkyl group such as methyl or ethyl, and R_{c4} is selected from the group consisting of alkyl such as C₄-₁₆ alkyl, vinyl, vinyl alkyl, ω-glycidoxyalkyl such as 3-glycidoxypropyl, ω-mercaptoalkyl such as 3-mercaptopropyl, ω-acryloxyalkyl such as 3-acryloxypropyl, and ω-methacryloxyalkyl such as 3-methacryloxypropyl, among others. In a specific embodiment, the coupling agent is a compound as shown below:

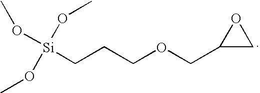

Other exemplary coupling agents comprise compounds that contain both silane and mercapto moieties, illustrative examples of which comprise mercaptomethyltriphenylsilane, beta-mercaptoethyltriphenylsilane, beta-mercaptopropyltriphenyl-silane, gamma-mercaptopropyldiphenylmethyl-silane, gamma-mercaptopropylphenyldimethyl-silane, delta-mercaptobutylphenyldimethyl-silane, delta-mercaptobutyltriphenyl-silane, tris(beta-mercaptoethyl)phenylsilane, tris(gamma-mercaptopropyl)phenylsilane, tris(gamma-mercaptopropyl)methylsilane, tris(gamma-mercaptopropyl)ethylsilane, tris(gamma-mercaptopropyl)benzylsilane, and the like.

In a variety of exemplary embodiments, the formulation may optionally include silsesquioxane polymers to lend better mechanical integrity.

To lessen degradation of encapsulant, stabilizers such as thermal stabilizers and UV-stabilizers may be added in the formulation of the present invention as optional component. Examples of stabilizers are described in J. F. Rabek, “Photostabilization of Polymers; Principles and Applications”, Elsevier Applied Science, NY, 1990 and in “Plastics Additives Handbook”, 5^{th} edition, edited by H. Zweifel, Hanser Publishers, 2001.

Illustrative examples of suitable stabilizers include organic phosphites and phosphonites, such as triphenyl phosphite, diphenylalkyl phosphites, phenyidialkyl phosphites, tri-(nonylphenyl) phosphite, trilauryl phosphite, trioctadecyl phosphite, di-stearyl-pentaerythritol diphosphite, tris-(2,4-di-tert-butylphenyl) phosphite, di-isodecylpentaerythritol diphosphite, di-(2,4-di-tert-butylphenyl) pentaerythritol diphosphite, tristearyl-sorbitol triphosphite, and tetrakis-(2,4-di-tert-butylphenyl)-4,4′-biphenyldiphosphonite.

Illustrative examples of suitable stabilizers include sulfur-containing phosphorus compounds such as trismethylthiophosphite, trisethylthiophosphite, trispropylthiophosphite, trispentylthiophosphite, trishexylthiophosphite, trisheptylthiophosphite, trisoctylthiophosphite, trisnonylthiophosphite, trislaurylthiophosphite, trisphenylthiophosphite, trisbenzylthiophosphite, bispropiothiomethylphosphite, bispropiothiononylphosphite, bisnonylthiomethylphosphite, bisnonylthiobutylphosphite, methylethylthiobutylphosphite, methylethylthiopropiophosphite, methylnonylthiobutylphosphite, methylnonylthiolaurylphosphite, and pentylnonylthiolaurylphosphite.

Suitable stabilizers may comprise sterically hindered phenols. Illustrative examples of sterically hindered phenol stabilizers include 2-tertiary-alkyl-substituted phenol derivatives, 2-tertiary-amyl-substituted phenol derivatives, 2-tertiary-octyl-substituted phenol derivatives, 2-tertiary-butyl-substituted phenol derivatives, 2,6-di-tertiary-butyl-su-bstituted phenol derivatives, 2-tertiary-butyl-6-methyl- (or 6-methylene) substituted phenol derivatives, and 2,6-di-methyl-substituted phenol derivatives. In certain particular embodiments of the present invention, sterically hindered phenol stabilizers comprise alpha-tocopherol and butylated hydroxy toluene.

Suitable stabilizers include sterically hindered amines, illustrative examples of which comprise bis-(2,2,6,6-tetramethylpiperidyl-)sebacate, bis-(1,2,2,6,6-pentamethylpiperidyl)sebacate, n-butyl-3,5-di-tert-ebutyl-4-hydroxybenzyl malonic acid bis-(1,2,2,6,6-pentamethylpiperidyl)ester, condensation product of 1-hydroxyethyl-2,2,6,6-tetramethyl-4-hydroxypiperidine and succinic acid, condensation product of N,N′-(2,2,6,6-tetramethylpiperidyl)-hexamethylene-diamine and 4-tert-octyl-amino-2,6-dichloro-s-triazine, tris-(2,2,6,6-tetramethylpiperidyl)-nitrilotriacetate, tetrakis-(2,2,6,6-tetramethyl-4-piperidyl)-1,2,3,4-butanetetracarboxylate, and 1,1′-(1,2-ethanediyl)-bis-(3,3,5,5-tetramethylpiperazinone) etc.

Suitable stabilizers include compounds which destroy peroxide, illustrative examples of which comprise esters of beta-thiodipropionic acid, for example the lauryl, stearyl, myristyl or tridecyl esters; mercaptobenzimidazole or the zinc salt of 2-mercaptobenzimidazole; zinc dibutyl-dithiocarbamate; dioctadecyl disulfide; and pentaerythritol tetrakis-(beta-dodecylmercapto)-propionate.

Other optional components may include phosphor particles. The phosphor particles may be prepared from larger pieces of phosphor material by any grinding or pulverization method, such as ball milling using zirconia-toughened balls or jet milling. They also may be prepared by crystal growth from solution, and their size may be controlled by terminating the crystal growth at an appropriate time. An exemplary phosphor is the cerium-doped yittrium aluminum oxide Y₃Al₅O₁₂ garnet (“YAG:Ce”). Other suitable phosphors are based on YAG doped with more than one type of rare earth ions, such as (Y_{1-x-y}GdₓCe_{y})₃Al₅O₁₂ (“YAG:Gd,Ce”), (Y₁₋ₓCeₓ)₃(Al_{5-y}Ga_{y})O₁₂ (“YAG:Ga,Ce”), (Y_{1-x-y}GdₓCe_{y})(Al_{5-z}Ga_{z})O₁₂ (“YAG:Gd,Ga,Ce”), and (Gd₁₋ₓCeₓ)Sc₂Al₃O₁₂ (“GSAG”), where 0≦x≦1, 0≦y≦1, 0≦z≦5, and x+y≦1. For example, the YAG:Gd,Ce phosphor shows an absorption of light in the wavelength range from about 390 nm to about 530 nm (i.e., the blue-green spectral region) and an emission of light in the wavelength range from about 490 nm to about 700 nm (i.e., the green-to-red spectral region). Related phosphors include Lu₃Al₅O₁₂ and Tb₂Al₅O₁₂, both doped with cerium. In addition, these cerium-doped garnet phosphors may also be additionally doped with small amounts of Pr (such as about 0.1-2 mole percent) to produce an additional enhancement of red emission. Non-limiting examples of phosphors that are efficiently excited by radiation of 300 nm to about 500 nm include green-emitting phosphors such as Ca₈Mg(SiO₄)₄Cl₂:Eu²⁺, Mn²⁺; GdBO₃:Ce³⁺, Tb³⁺; CeMgAl₁₁O₁₉:Tb³⁺; Y₂SiO₅:Ce³⁺, Tb³⁺; and BaMg₂Al₁₆O₂₇:Eu²⁺, Mn²⁺ etc.; red-emitting phosphors such as Y₂O₃:Bi³⁺, Eu³⁺; Sr₂P₂O₇:Eu²⁺, Mn²⁺; SrMgP₂O₇:Eu²⁺,Mn²⁺; (Y,Gd)(V,B)O₄:Eu³⁺; and 3.5MgO.0.5MgF₂.GeO₂:Mn⁴⁺ (magnesium fluorogermanate) etc.; blue-emitting phosphors such as BaMg₂Al₁₆O₂₇:Eu²⁺; Sr₅(PO₄)₁₀Cl₂:Eu²⁺; (Ba,Ca,Sr)(PO₄)₁₀(Cl,F)₂:Eu²⁺; and (Ca,Ba,Sr)(Al,Ga)₂S₄:Eu²⁺ etc.; and yellow-emitting phosphors such as (Ba,Ca,Sr)(PO₄)₁₀(Cl,F)₂:Eu²⁺, Mn²⁺ etc. Still other ions may be incorporated into the phosphor to transfer energy from the emitted light to other activator ions in the phosphor host lattice as a way to increase the energy utilization. For example, when Sb³⁺ and Mn²⁺ ions exist in the same phosphor lattice, Sb³⁺ efficiently absorbs light in the blue region, which is not absorbed very efficiently by Mn²⁺, and transfers the energy to Mn²⁺ ion. Thus, a larger total amount of light from light emitting diode is absorbed by both ions, resulting in higher quantum efficiency.

Other optional components may include one or more refractive index modifiers. Non-limiting examples of suitable refractive index modifiers are compounds of Groups II, III, IV, V, and VI of the Periodic Table. Non-limiting examples are titanium oxide, hafnium oxide, aluminum oxide, gallium oxide, indium oxide, yttrium oxide, zirconium oxide, cerium oxide, zinc oxide, magnesium oxide, calcium oxide, lead oxide, zinc selenide, zinc sulphide, gallium nitride, silicon nitride, aluminum nitride, or alloys of two or more metals of Groups II, III, IV, V, and VI such as alloys made from Zn, Se, S, and Te.

As a person skilled in the art can appreciate, many other optional components may be included in the formulation. For example, reactive or unreactive diluent (to decrease viscosity), flame retardant, mold releasing additives, anti-oxidant, and plasticizing additive etc., may be advantageously incorporated therein.

As described supra, the present invention also provides a method of preparing an optoelectronic device, which comprises (i) providing a light emitting semiconductor, and (ii) encapsulating the light emitting semiconductor with an encapsulant that is made from a formulation comprising an epoxy isocyanurate and a curing agent. The light emitting semiconductor may be a light emitting diode (LED) or a laser diode.

The encapsulant of the present invention can be prepared by combining various formulation components, and optional components if desired, in any convenient order. In various embodiments, all the components may be mixed together. In other embodiments, two or more components may be premixed and then subsequently combined with other components.

The formulation of the present invention may be hand mixed but also can be mixed by standard mixing equipment such as dough mixers, chain can mixers, planetary mixers, and the like. The blending can be performed in batch, continuous, or semi-continuous mode.

Although any suitable polymer processing techniques may be employed in encapsulation of the optoelectronic device, resin transfer molding and/or casting are preferred. In a variety of exemplary embodiments, the encapsulating material prepared according to the above formulation is resin transfer moldable, castable, or both.

In transfer (or plunger) molding, the to-be-molded material is introduced through a small opening or gate after the mold is closed. This process can be used when additional material such as glass or other designed object such as a LED apparatus, are placed in the mold prior to closing the mold. In real-world transfer or pot-type molding, the mold is closed and placed in a press, the clamping action of which keeps the mold closed. The material is introduced into an open port at the top of the mold. A plunger is placed into the pot, and the press is closed. As the press closes, it pushes against the plunger forcing the molding material into the mold cavity. Excess molding material may be added to ensure that that there is sufficient material to fill the mold. After the material is cured to a required extent, the plunger and the part are removed from the mold.

In preparing a castable material, at least two methods may be used to control the physical properties such as viscosity of the encapsulating material to meet the requirements for casting. In the first method, the encapsulant formulation is lightly, or not densely, crosslinked. In the second method, polymerization of the encapsulant formulation is controlled to such an extent that is suitable for casting. For example, the polymerization rate can be controlled effectively to allow a castable form of the material to be produced. Preferably, the two methods are combined. In practice, special shapes, tubes, rods, sheets, and films may be produced from the castable material of the invention without added pressure in the processing. In casting, the composition according to the formulation may be e.g. heated to a fluid, poured into a mold, cured, and removed from the mold. As a skilled artisan can understand, various technical benefits may be achieved from this aspect of the invention, such as flexibility of the encapsulating material to adapt to novel LED package design; and controllable polymerization chemistry; among others.

In a variety of exemplary embodiments, after an optoelectronic device is enveloped in the uncured formulation, typically performed in a mold, the formulation is cured. The curing may be conducted in one or more stages using methods such as thermal, UV, electron beam techniques, or combinations thereof. For example, thermal cure may be performed at temperatures in one embodiment in a range of between 20° C. and about 200° C., in another embodiment in a range between about 80° C. and about 200° C., in still another embodiment in a range between about 100° C. and about 200° C., and in still another embodiment in a range between about 120° C. and about 160° C. Also in other embodiments the formulation can be photo-chemically cured, initially at about room temperature. Although some thermal excursion from the photochemical reaction and subsequent cure can occur, no external heating is typically required. In other embodiments, the formulations may be cured in two stages wherein an initial thermal or UV cure, for example, may be used to produce a partially hardened or B-staged epoxy resin. This material, which is easily handled, may then be further cured using, for example, either thermal or UV techniques, to produce a material which gives the optoelectronic device desired performances.

In a specific embodiment of the invention, the reaction between two epoxy monomers, trisglycidyl isocyanurate and ERL 4221 with hexahydro-4-methylphthalic anhydride catalyzed by 2-phenylimidazole yielded a cured composition exhibiting improved UV and thermal properties. The material can be cured in B-stage form by low temperature and low rate propagating catalysis, with subsequent curing at 150° C. The use of 2-phenylimidazole as catalyst for achieving B-stage is unique due to its lower acidity and reactivity than conventional epoxidation catalyst.

In a variety of exemplary embodiments, the optoelectronic device of the invention possesses numerous benefits, such as UV stabilization package, increased thermal stability, commercially available raw materials, B or C stage curing capability, optical clarity, catalyst system, and good Tg characteristics such as slightly above 150°, among others.

In a variety of exemplary embodiments, the addition of trisglycidylisocyanurate improves the UV resistance of some aliphatic or cylcoaliphatic epoxy systems that would otherwise degrade under UV exposure.

The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

In examples 1-10, TGIC and EHEHA were used as the epoxy compounds. MHHPA was used as the anhydride curing agent. 2-phenylimidazole was used as the catalyst.

TABLE 1

| | Molar | Group | | | |
|---|---|---|---|---|---|
| | Ratio | Molar Ratio | | | |
| | (TGIC/ | (Epoxy/ | Reaction | | |
| Example | EHEHA) | Anhydride) | condition | B-stage | Appearance |
| 1 | 5:1 | 1:1 | 50° C. | No | Colorless |
| 2 | 4:1 | 1:1 | 50° C. | No | Colorless |
| 3 | 3:1 | 1:1 | 50° C. | Partial | Colorless |
| 4 | 2:1 | 1:1 | 50° C. | Partial | Colorless |
| 5 | 1:1 | 1:1 | 50° C. | Partial | Colorless |
| 6 | 1:2 | 1:1 | 50° C. | Partial | Colorless |
| 7 | 1:3 | 1:1 | 50° C. | Yes | Colorless |
| 8 | 1:4 | 1:1 | 50° C. | Yes | Colorless |
| 9 | 1:5 | 1:1 | 50° C. | Yes | Colorless |
| 10 | 0:1 | 1:1 | 50° C. | Yes | Colorless |

As indicated by Table 1, B-stage could be obtained by decreasing the ratio of TGIC to EHEHA. Ten samples were prepared from corresponding B-stage samples. All the samples were cured at 100° C. for 2 h and 150° C. for 2 h. The Tg and CTE data are listed in Table 2.

TABLE 2
Tg and CTE from TMA

| | CTE below Tg | | CTE above Tg |
|---|---|---|---|
| Example | (μm/m/° C.) | Tg (° C.) | (μm/m/° C.) |
| 1 | 73 | 173 | 191 |
| 2 | 72 | 175 | 234 |
| 3 | 62 | 175 | 193 |
| 4 | 88 | 197 | 202 |
| 5 | 66 | 180 | 192 |
| 6 | 74 | 182 | 198 |
| 7 | 65 | 158 | 215 |
| 8 | 75 | 166 | 194 |
| 9 | 71 | 153 | 202 |
| 10 | 78 | 150 | 210 |

The reactions between two epoxy monomers, trisglycidyl isocyanurate and ERL 4221 with hexahydro-4-methylphthalic anhydride catalyzed by 2-phenylimidazole yielded a cured composition exhibiting improved UV and thermal properties. The material can be cured in B-stage form by low temperature and low rate propagating catalysis, with subsequent curing at 150° C. The use of 2-phenylimidazole as catalyst for achieving B-stage is unique due to its lower acidity and reactivity than conventional epoxidation catalyst.

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims. All patents and publications cited herein are incorporated herein by reference.

1. An optoelectronic device comprising a light emitting semiconductor and an encapsulant, in which the encapsulant is made from an encapsulant formulation comprising an epoxy isocyanurate and a curing agent.

2. The optoelectronic device according to claim 1, in which the epoxy isocyanurate has one of the following formulas: 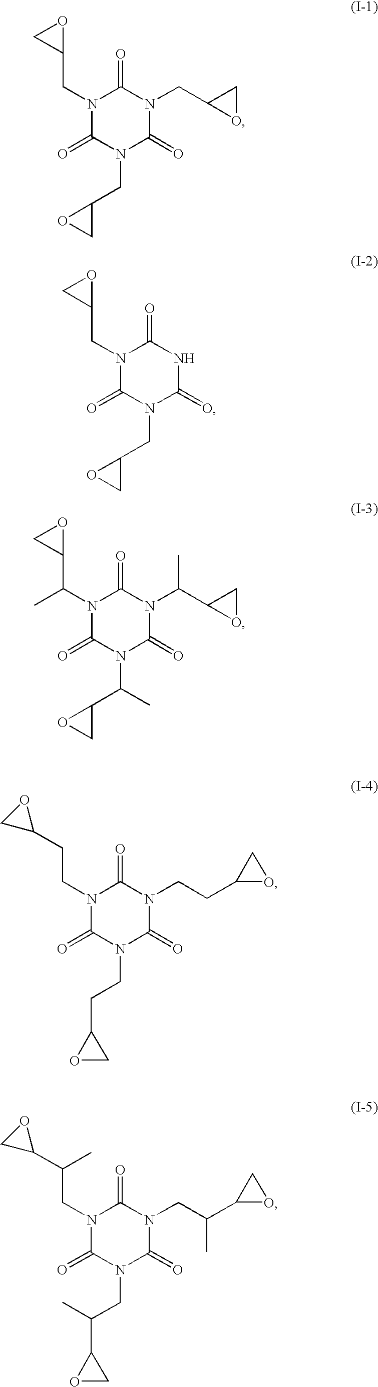 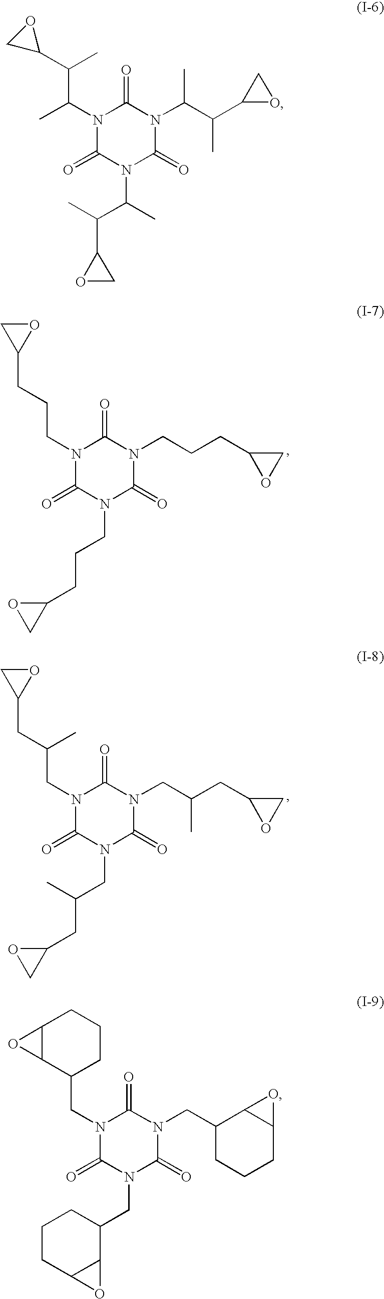 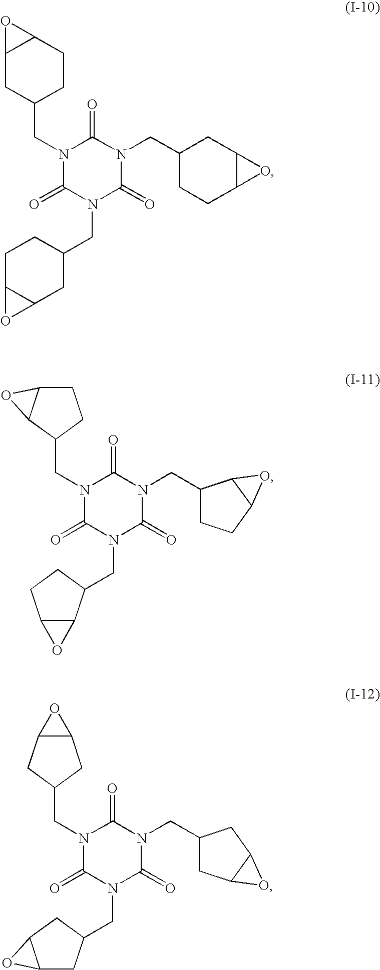
and the mixture thereof.

3. The optoelectronic device according to claim 1, in which the epoxy isocyanurate comprises a compound of formula (I-1) as shown below:

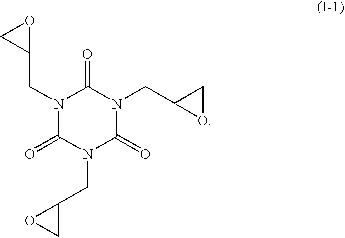

4. The optoelectronic device according to claim 1, in which the amount of the epoxy isocyanurate is between about 10% and about 50%, based on the total weight of the encapsulant formulation.

5. The optoelectronic device according to claim 1, in which the encapsulant formulation further comprising an epoxy compound other than the epoxy isocyanurate.

6. The optoelectronic device according to claim 5, in which the epoxy compound is selected from the group consisting of 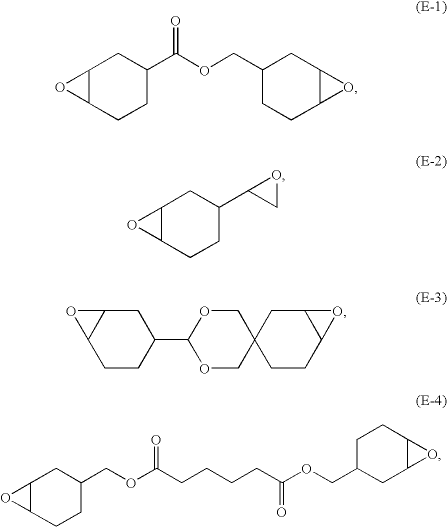
and mixture thereof.

7. The optoelectronic device according to claim 5, in which the amount of the epoxy compound is between about 50% and about 80%, based on the total weight of the encapsulant formulation.

8. The optoelectronic device according to claim 1, in which the encapsulant formulation comprises an epoxy isocyanurate of formula (I-1) and an epoxy compound of formula (E-1):

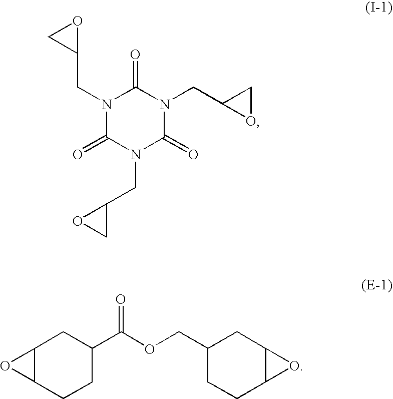

9. The optoelectronic device according to claim 1, in which the curing agent is selected from cycloaliphatic anhydrides, aliphatic anhydrides, polyacids and their anhydrides, polyamides, formaldehyde resins, aliphatic polyamines, cycloaliphatic polyamines, aromatic polyamines, polyamide amines, polycarboxylic polyesters, polysulfides and polymercaptans, phenol novolac resins, polyols, and mixture thereof.

10. The optoelectronic device according to claim 1, in which the curing agent comprises an anhydride of formula (A-1):

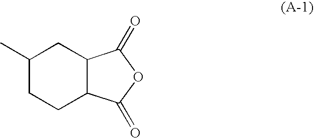

11. The optoelectronic device according to claim 1, in which the amount of the curing agent is between about 20% and about 60%, based on the total weight of the encapsulant formulation.

12. The optoelectronic device according to claim 1, in which the encapsulant formulation comprises an epoxy isocyanurate of formula (I-1), an epoxy compound of formula (E-1), and an anhydride of formula (A-1):

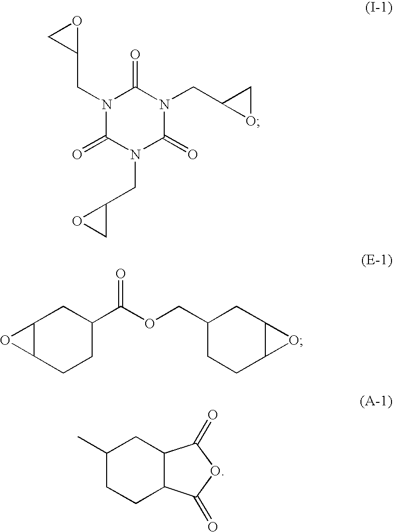

13. The optoelectronic device according to claim 1, in which the encapsulant formulation further comprising a catalyst.

14. The optoelectronic device according to claim 13, in which the catalyst is selected from the group consisting of imidazole compounds, tertiary amine compounds, phosphine compounds, cycloamidine compounds, and mixture thereof.

15. The optoelectronic device according to claim 14, in which the imidazole compound is selected from the group consisting of 2-methylimidazole, 2-ethyl-4-methylimidazole, 2-phenylimidazole, and mixture thereof.

16. The optoelectronic device according to claim 13, in which the amount of the catalyst is between about 0.01% and about 20%, based on the total weight of the encapsulant formulation.

17. The optoelectronic device according to claim 1, in which the encapsulant formulation comprises an epoxy isocyanurate of formula (I-1), an epoxy compound of formula (E-1), an anhydride of formula (A-1), and a catalyst of formula (C-1):

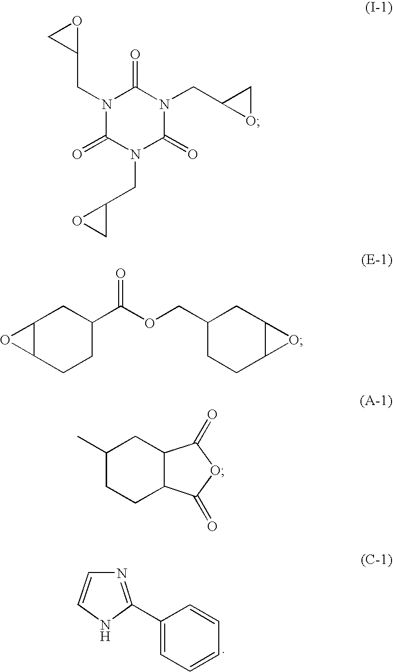

18. The optoelectronic device according to claim 1, in which the light emitting semiconductor is a light emitting diode (LED) or a laser diode.

19. A method of preparing an optoelectronic device, which comprises
(i) providing a light emitting semiconductor, and
(ii) encapsulating the light emitting semiconductor with an encapsulant that is made from a formulation comprising an epoxy isocyanurate and a curing agent.

20. The method according to claim 19, in which the epoxy isocyanurate comprises a compound of formula (I-1):

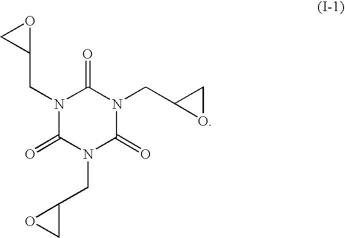

21. An encapsulant composition comprising an epoxy isocyanurate and a curing agent.

22. The encapsulant composition according to claim 21, in which the epoxy isocyanurate comprises a compound of formula (I-1): [chemical structure]
